(19) United States
(12) Patent Application Publication
(10) Pub. No.: US 2025/0160054 A1
(43) Pub. Date: May 15, 2025

(54) PIEZOELECTRIC HETEROSYSTEMS AND METHODS OF MANIPULATING THE PROPERTIES THEREOF

(71) Applicant: Purdue Research Foundation, West Lafayette, IN (US)

(72) Inventors: Tillmann C. Kubis, West Lafayette, IN (US); Han-Wei Hsiao, West Lafayette, IN (US)

(73) Assignee: Purdue Research Foundation, West Lafayette, IN (US)

(21) Appl. No.: 18/943,654

(22) Filed: Nov. 11, 2024

Related U.S. Application Data
(60) Provisional application No. 63/548,171, filed on Nov. 11, 2023.

(51) Int. Cl. H01L 33/00; G01L 1/16; H01L 29/84; H01L 33/06

(52) U.S. Cl. CPC H10H 20/811; G01L 1/16; H10D 48/50; H10H 20/812

(57) ABSTRACT

A piezoelectric material system includes a first material, a second material positioned near the first material, and a material adjustment mechanism. The first and second materials are operable to form a material interaction and define at least one collective material property. The material adjustment mechanism is configured to maintain the material interaction between the first material and second material at a user-specified material interaction, and the material adjustment mechanism is selectively operable to adjust the user-specified material interaction to thereby adjust the collective material property.

### CROSS-REFERENCE TO RELATED APPLICATIONS

This application is related to and claims the priority benefit of U.S. Provisional Patent Application No. 63/548,171, entitled “Piezoelectric Heterosystems and Methods of Manipulating the Properties Thereof,” filed Nov. 11, 2023, the contents of which are hereby incorporated by reference in their entirety into the present disclosure.

### TECHNICAL FIELD

The present application relates to material systems, and specifically to two-dimensional heterosystems and methods of adjusting the piezoelectric properties thereof.

### BACKGROUND

This section introduces aspects that may help facilitate a better understanding of the disclosure. Accordingly, these statements are to be read in this light and are not to be understood as admissions about what is or is not prior art.

Two-dimensional heteromaterials consist of different two-dimensional material layers stacked on top of each other to form a heterostructure. These materials can exhibit a wide range of unique and tunable properties, including piezoelectricity. Piezoelectricity is the ability of certain materials to generate an electric charge when subjected to mechanical stress or deformation, and vice versa. In the realm of two-dimensional heteromaterials, common piezoelectric properties include the piezoelectric coefficient, which quantifies their capacity to generate an electric charge in response to mechanical strain. These materials often exhibit mechanical flexibility, and by combining layers with distinct piezoelectric properties, the overall piezoelectric response of the heteromaterial can be engineered.

Additionally, they can be integrated with three-dimensional materials to create hybrid systems with unique piezoelectric behaviors. Researchers are actively exploring these materials for various applications, particularly in the development of nanoscale devices for sensing, energy harvesting, and other technologies, where their small size and flexibility offer advantages over traditional bulk piezoelectric materials.

### SUMMARY

Aspects of this disclosure describe a piezoelectric material system. The piezoelectric material system can include a first material, a second material positioned near the first material, and a material adjustment mechanism. The first and second materials can be operable to form a material interaction and define at least one collective material property, and the material adjustment mechanism can be configured to maintain the material interaction between the first material and second material at a user-specified material interaction. Further, the material adjustment mechanism can be selectively operable to adjust the user-specified material interaction to thereby adjust the collective material property. In some embodiments, the user-specified material interaction can include at least one of a distance, twist angle, defect density, defect charge, polarization, corrugation, or coupling strength between the first and second materials. In still some embodiments, the collective material property can include at least one of piezoelectricity, polarization, charge conductance, heat conductance, ON current, OFF current, or subthreshold slope.

In some embodiments of the piezoelectric material system, the material adjustment mechanism can include one of a growth interaction, an external strain, an internal strain, a temperature, an external field, an internal field, a vicinity effect, an encapsulation by one or more other materials, a twist angle, a charge current, a heat current, defects, or a corrugation. In other embodiments, the material interaction can include one of a coulomb interaction, a quantum mechanical interaction, a phonon interaction, a short-range interaction, or a long-range interaction.

In further embodiments, the first material can be a 3D material, a 2D material, a transition metal dichalcogenide, an oxide, a metal, a group IV element, a group III-V element, a group II-VI element, or an alloy, and the second material can be a 3D material, a 2D material, a transition metal dichalcogenide, an oxide, a metal, a group IV element, a group III-V element, a group II-VI element, or an alloy.

This summary is provided to introduce a selection of the concepts that are described in further detail in the detailed description and drawings contained herein. This summary is not intended to identify any primary or essential features of the claimed subject matter. Some or all of the described features may be present in the corresponding independent or dependent claims, but should not be construed to be a limitation unless expressly recited in a particular claim. Each embodiment described herein does not necessarily address every object described herein, and each embodiment does not necessarily include each feature described. Other forms, embodiments, objects, advantages, benefits, features, and aspects of the present disclosure will become apparent to one of skill in the art from the detailed description and drawings contained herein. Moreover, the various apparatuses and methods described in this summary section, as well as elsewhere in this application, can be expressed as a large number of different combinations and subcombinations. All such useful, novel, and inventive combinations and subcombinations are contemplated herein, it being recognized that the explicit expression of each of these combinations is unnecessary.

### BRIEF DESCRIPTION OF THE DRAWINGS

While the specification concludes with claims which particularly point out and distinctly claim this technology, it is believed this technology will be better understood from the following description of certain examples taken in conjunction with the accompanying drawings, in which like reference numerals identify the same elements and in which:

FIG. 1 depicts a graphical representation of the out-of-plane piezoelectric coefficient of MoS2/h-BN as a function of interlayer distance and the twist angle, showing how the piezoelectric coefficient correlates with the interlayer distance and twist angle;

FIG. 2 depicts a schematic diagram showing one example heterostructure having a material adjustment mechanism coupled thereto;

FIG. 3 depicts a schematic diagram showing an example transistor having a 2D piezoelectric material layer;

FIG. 4 depicts a schematic diagram showing a first example of a multi-quantum well (MQW) light emitting diode (LED) having a 2D piezoelectric material layer;

FIG. 5 depicts a schematic diagram showing a second example of a MQW LED having a 2D piezoelectric material layer;

FIG. 6 depicts a schematic diagram showing a third example of a MQW LED having a 2D piezoelectric material layer;

FIG. 7 depicts a schematic diagram showing a fourth example of a MQW LED having a 2D piezoelectric material layer;

FIG. 8 depicts a schematic diagram showing an example of a MQW LED having a plurality of 2D piezoelectric material layers;

FIG. 9 depicts a schematic diagram showing an example pressure sensor having a 2D piezoelectric material layer;

FIG. 10 depicts a schematic diagram showing an example stress-gated transistor having a 2D piezoelectric material layer;

FIG. 11 depicts a schematic diagram showing a first example of a thin-film transistor having a 2D piezoelectric material layer;

FIG. 12 depicts a schematic diagram showing a second example of a thin-film transistor having a 2D piezoelectric material layer; and

FIG. 13 depicts a schematic diagram showing a third example of a thin-film transistor having a 2D piezoelectric material layer.

The drawings are not intended to be limiting in any way, and it is contemplated that various embodiments of the technology may be carried out in a variety of other ways, including those not necessarily depicted in the drawings. The accompanying drawings incorporated in and forming a part of the specification illustrate several aspects of the present technology, and together with the description serve to explain the principles of the technology; it being understood, however, that this technology is not limited to the precise arrangements shown, or the precise experimental arrangements used to arrive at the various graphical results shown in the drawings.

### DETAILED DESCRIPTION

The following description of certain examples of the technology should not be used to limit its scope. Other examples, features, aspects, embodiments, and advantages of the technology will become apparent to those skilled in the art from the following description, which is by way of illustration, one of the best modes contemplated for carrying out the technology. As will be realized, the technology described herein is capable of other different and obvious aspects, all without departing from the technology. Accordingly, the drawings and descriptions should be regarded as illustrative in nature and not restrictive.

It is further understood that any one or more of the teachings, expressions, embodiments, examples, etc. described herein may be combined with any one or more of the other teachings, expressions, embodiments, examples, etc. that are described herein. The following-described teachings, expressions, embodiments, examples, etc. should therefore not be viewed in isolation relative to each other. Various suitable ways in which the teachings herein may be combined will be readily apparent to those of ordinary skill in the art in view of the teachings herein. Such modifications and variations are intended to be included within the scope of the claims.

Piezoelectric systems or devices may contain two general components or layers, which may or may not be constructed from piezoelectric materials. Substantial changes may be induced in the piezoelectric coefficients through external alterations, without mandating the use of piezoelectric materials in both components. External alterations, such as adjusting the distance between the components, varying twist angles, or introducing defects, can be employed to enhance the piezoelectric response. The orientation of the piezoelectric response, whether in-plane or out-of-plane, can be irrelevant, as the emphasis is on the significant change in piezoelectric coefficients. Decreasing the distance between two components in a piezoelectric device may lead to a significant change in piezoelectric coefficients because it intensifies electron density and charge redistribution. As the components draw closer, the material experiences stronger electrostatic forces, causing the formation of electric dipoles and higher polarization. This results in a more pronounced piezoelectric response, making the system or device more sensitive to mechanical stress due to increased charge concentration and dipole alignment. Further, these concepts are not restricted to 2D heterostruct structures and can be extended to bilayer systems with identical layers, multilayer structures, as well as 2D and 3D materials, including transition metal dichalcogenide, oxide, metal, group IV, III-V, II-VI, magnetic materials, topological materials etc. This adaptability ensures a wide range of potential applications for the device.

Another mechanism for achieving enhanced piezoelectric sensitivity is the formation of corrugations when two materials are combined. Interlayer interactions can induce these corrugations, leading to a high piezoelectric response. The application of external alterations can further amplify this effect, enabling the system to maintain a piezoelectrically sensitive state. Corrugations, or periodic surface or structural variations, can induce asymmetry in the material. This asymmetry can lead to variations in charge distribution, creating electric dipoles. These dipoles respond to mechanical deformation, enhancing the piezoelectric effect. Corrugations can act as stress concentrators, increasing localized strains and electric field gradients, thereby amplifying the piezoelectric response in those regions.

In the context of 2D materials or heterobilayer structures, the twist angle between layers can have a significant impact. When the twist angle is carefully controlled, it can affect the electronic structure, creating a moiré pattern and altering the charge distribution. This twist-induced modulation of electronic properties can enhance the material's piezoelectric properties, resulting in a stronger response to mechanical perturbations. Further, controlled defects introduced into the material can disrupt the regular lattice structure, leading to local variations in charge distribution. This lattice distortion may create electric dipoles that respond to mechanical deformations, resulting in an increased piezoelectric response. Additionally, defects can promote the formation of ferroelectric domains within the material, each with distinct polarization orientations, allowing for a broader range of responses to mechanical stress, further enhancing the overall piezoelectric sensitivity of the device.

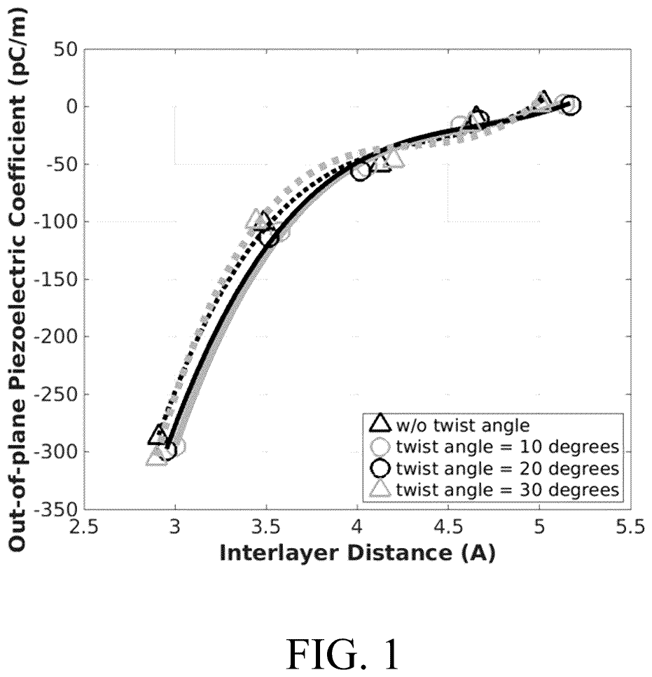

A series of numerical experiments were performed to investigate the correlation between the out-of-plane piezoelectric coefficient and interlayer distance. In the experiments, the interlayer spacing was shifted upward by 10% and downward by up to 30% after structural relaxation. It was found that e₃₃ changes nonlinearly with respect to this interlayer shift, and its absolute value increases by a factor of 10× compared to the equilibrium distance, as shown in FIG. 1.

Systems and devices designed to include and take advantage of the concepts described above provide value in various applications, including exceptionally sensitive pressure and touch sensors. They can also be utilized in piezoelectric transistors, where minimal force, deformation, or strain can generate substantial electric field or voltage responses. Additionally, they find utility in multi-quantum-well light-emitting diodes for enhancing light emission control. They can also be used to implement active feedback control systems that continuously monitor and adjust the twist angle, distance, or defect configuration. Sensors and actuators can be integrated into the device to maintain the desired conditions or interactions in real-time. For example, a closed-loop control system can be used to ensure that the twist angle remains fixed at the desired value, or to adjust defect concentration.

High-precision manufacturing techniques can be employed to ensure that the twist angle and distance between components are accurately set during fabrication. Advanced lithography and alignment methods are commonly used for 2D materials and multilayer structures. Materials may be chosen with intrinsic stability and minimal sensitivity to external conditions. Some materials exhibit robust piezoelectric properties that are less affected by environmental changes. In some embodiments, the system or device may be encapsulated within protective coatings or enclosures to shield it from environmental factors that may affect sensitivity. These protective layers can also serve to maintain the fixed twist angle and defect configuration. Further, in-situ monitoring techniques may be used to track the device's performance during operation. This may involve the use of spectroscopy, microscopy, or electrical measurements to detect and correct deviations.

As described above, the piezoelectricity of 2D heterosystems (e.g., bilayer systems, or those being formed of two different materials) can be switched in two different ways. First, changes of the twist angle between the two materials can lead to changes in the in-plane piezoelectricity of the bilayer materials. Second, changes in the distance between the layers can lead to changes in the out-of-plane-piezoelectricity. Depending on the layer composition, a small change in the interlayer distance can even yield exponential changes of the out-of-plane piezoelectric coefficients. This allows for highly sensitive pressure and touch sensors as well as other electronic devices.

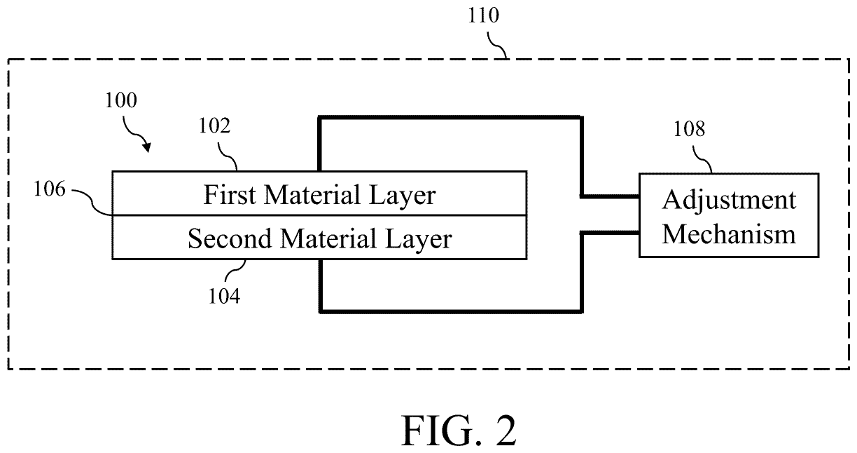

More particularly, as shown in FIG. 2, a heterostructure (100) is formed of a first material layer (102) and a second material layer (104), the interface between the two layers (102, 104) forming a heterojunction (106) which defines a collective material property of the heterostructure (100). The collective material property may be, for example, piezoelectricity, polarization, charge conductance, heat conductance, ON current, OFF current, or subthreshold slope. To make adjustments to the material property, an adjustment mechanism (108) can be provided. The adjustment mechanism (108) may be configured to adjust or maintain at least one of many material conditions, for example, a distance, twist angle, defect density, defect charge, polarization, corrugation, or coupling strength between the first and second materials, and the adjustment mechanism (108) may take one of many forms as required to make such adjustments. For example, the adjustment mechanism may be any one or more of a micromanipulator, twist-angle controlling CVD, or systems providing substrate engineering, laser-assisted techniques, atomic layer deposition, molecular beam epitaxy, thermal annealing, interlayer spacers, electrostatic gating, chemical interactions, mechanical exfoliation and transfer. It should be understood, however, that this list is not exhaustive and various other mechanisms may be used to provide to the functions described.

High-precision manufacturing techniques can be employed to ensure that the twist angle and distance between components are accurately set during fabrication. Advanced lithography and alignment methods are commonly used for 2D materials and multilayer structures. Materials may be chosen with intrinsic stability and minimal sensitivity to external conditions. Some materials exhibit robust piezoelectric properties that are less affected by environmental changes. In some embodiments, the heterostructure (100) (or, alternatively, the device which includes the heterostructure (100)) may be encapsulated within protective coatings or enclosures (110) to shield it from environmental factors that may affect sensitivity. Such shields can be oxide materials such as SiO₂, materials with wide band gaps such as hBN, dielectric layers such as HfO₂ and heavily doped materials that screen electrostatic fields. These protective layers can also serve to maintain the fixed twist angle and defect configuration. Further, in-situ monitoring techniques may be used to track the device's performance during operation. This may involve the use of spectroscopy, microscopy, or electrical measurements to detect and correct deviations.

Illustrated and described hereafter are various example devices, although it should be understood that these examples are not intended to represent an exhaustive list of applications.

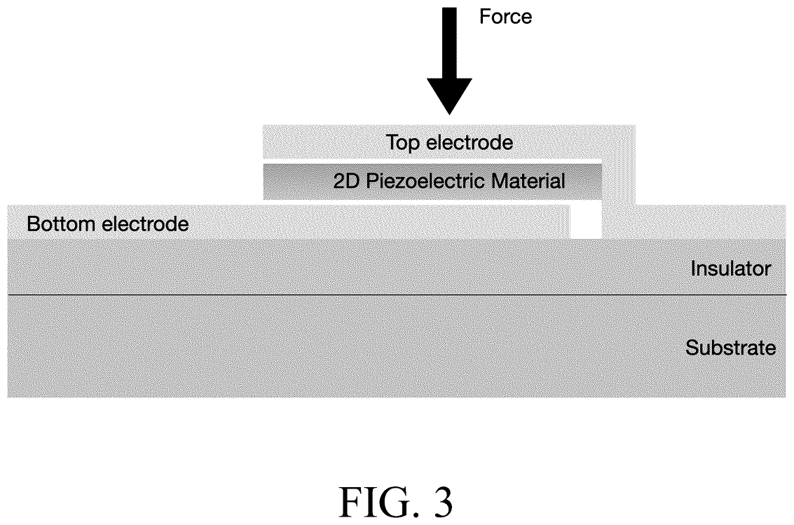

Shown in FIG. 3 is a piezoelectric transistor including a semiconductor channel positioned between two contacts. A 2D layer of piezoelectric material is positioned adjacent to or integrated with the semiconductor channel. When mechanical stress or strain is applied to the piezoelectric layer, the stress or strain induces a voltage difference across the 2D piezoelectric layer. This induced voltage subsequently impacts the electronic characteristics of the semiconductor channel. As described and illustrated above, the increased out-of-plane piezoelectric coefficients allow for smaller mechanical strains to induce significant changes in the electrical properties. As such, these 2D piezoelectric heterobilayer materials are useful for creating more sensitive and responsive piezotronic devices that can detect subtle mechanical changes.

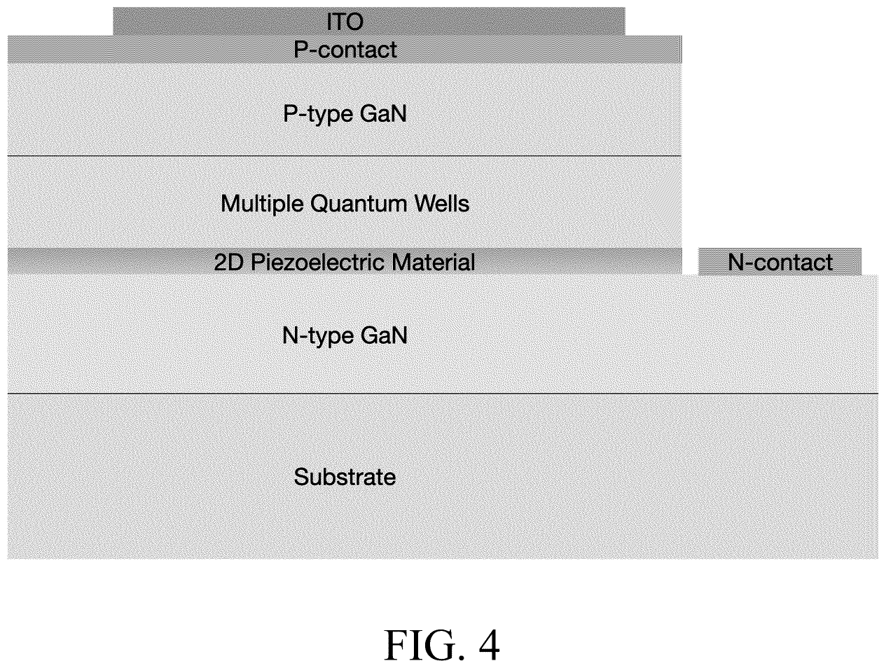

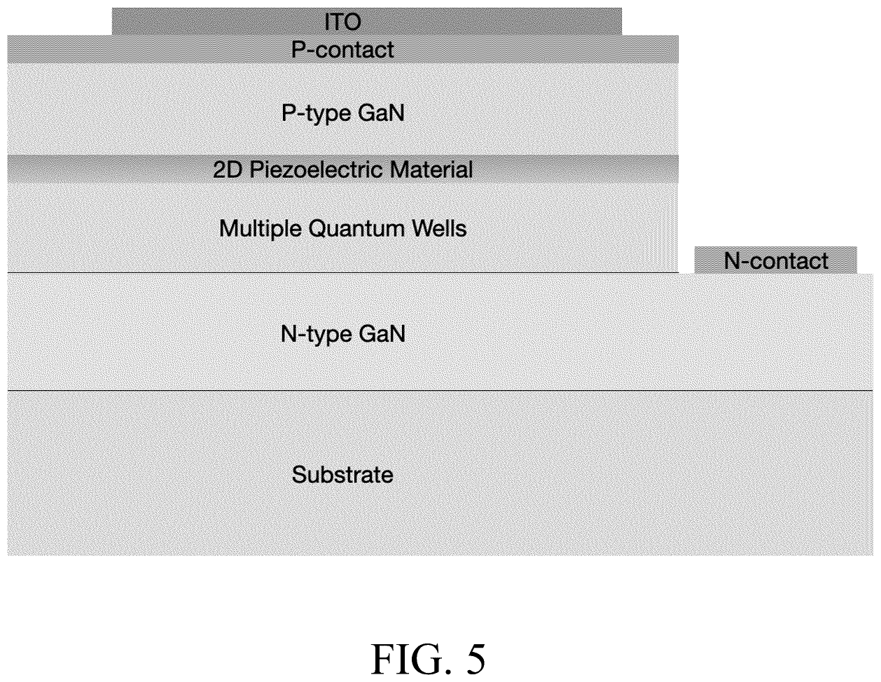

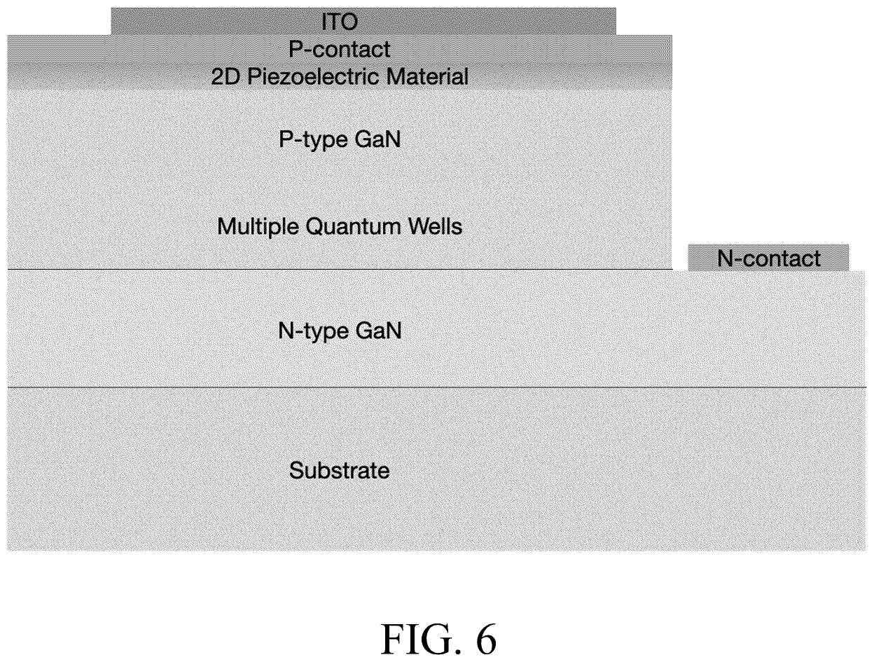

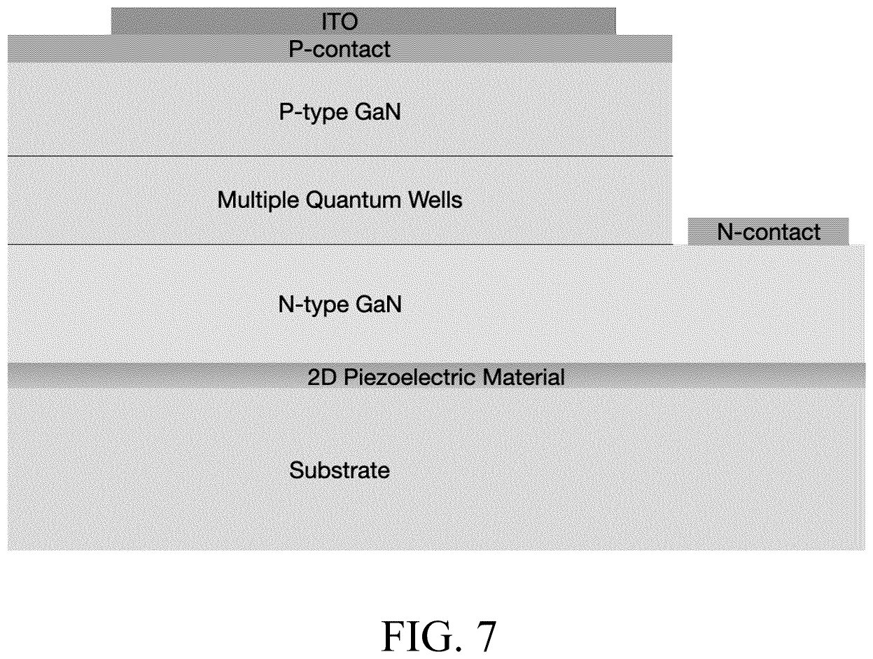

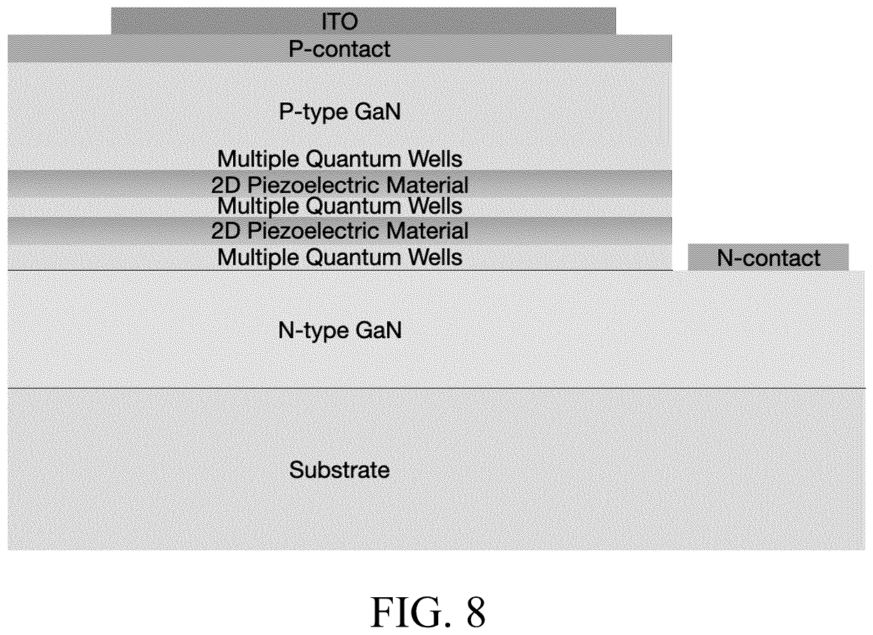

Shown in FIG. 4 is a common multi-quantum-well light emitting diode (MQW LED) structure with an additional 2D piezoelectric material layer included therein. The increased out-of-plane piezoelectric effect may be utilized to strain the LED's active region thereby tuning the emission wavelength. The piezoelectric-induced electric fields can also improve carrier injection or recombination, leading to enhanced LED performance. FIGS. 5-8 illustrate variations of the MQW LED structure having different 2D piezoelectric layer positions and different amounts of 2D piezoelectric layers positioned therein (see, FIG. 8).

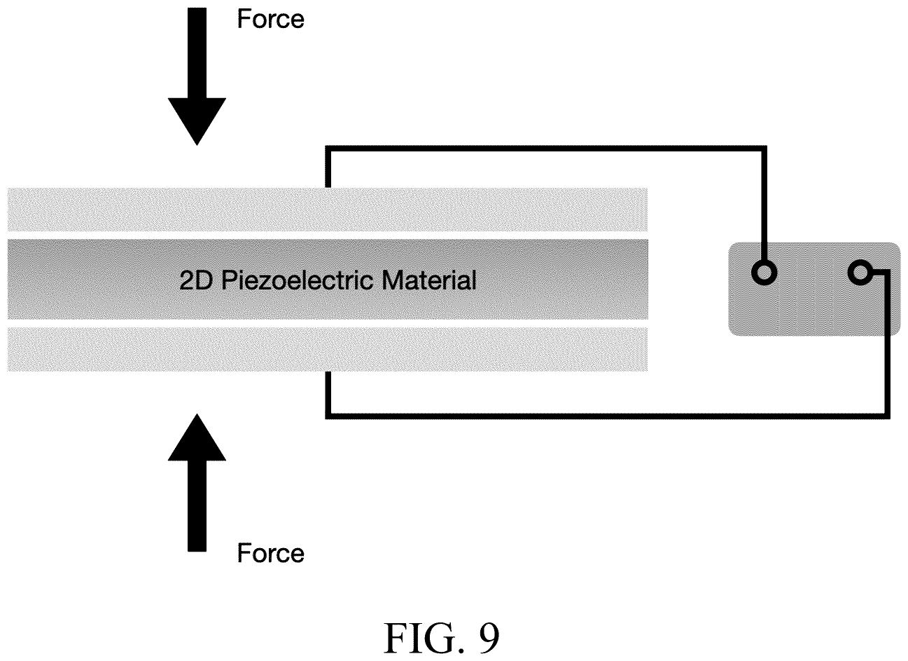

Shown in FIG. 9 is a 2D piezoelectric pressure sensor. When the 2D piezoelectric material is subjected to mechanical deformation along the out-of-plane direction (i.e., tensile or compressive stress), the separation of charges generates an electric potential difference across the 2D piezoelectric material. The generated electric charge or voltage can be measured using electrodes placed on the surface of the piezoelectric material as shown.

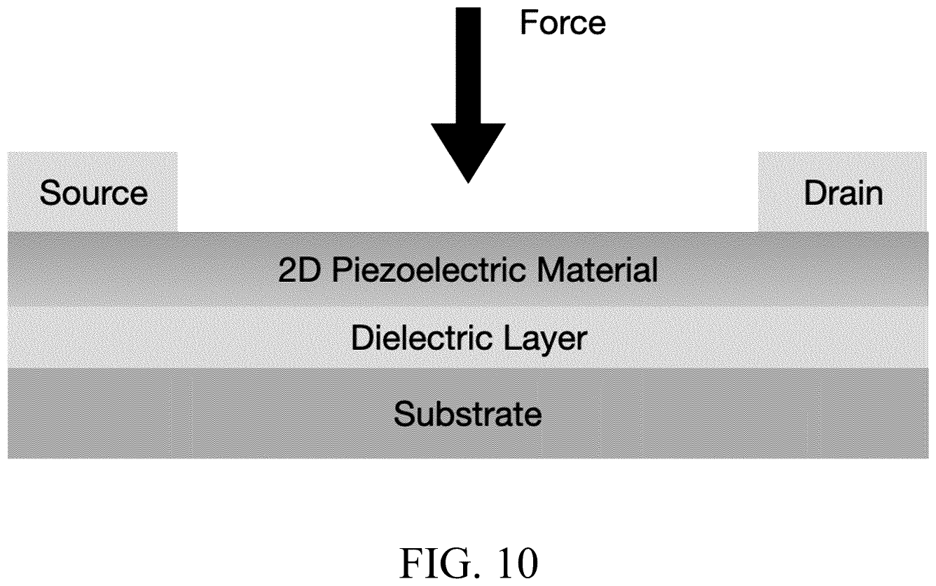

Shown in FIG. 10 is a stress-gated 2D piezoelectric transistor device. When an external force is applied to the 2D piezoelectric layer as shown, the generated piezoelectric charges can be configured to deplete the nearby carriers with the same polarity, resulting in a depletion region in the 2D piezoelectric material layer.

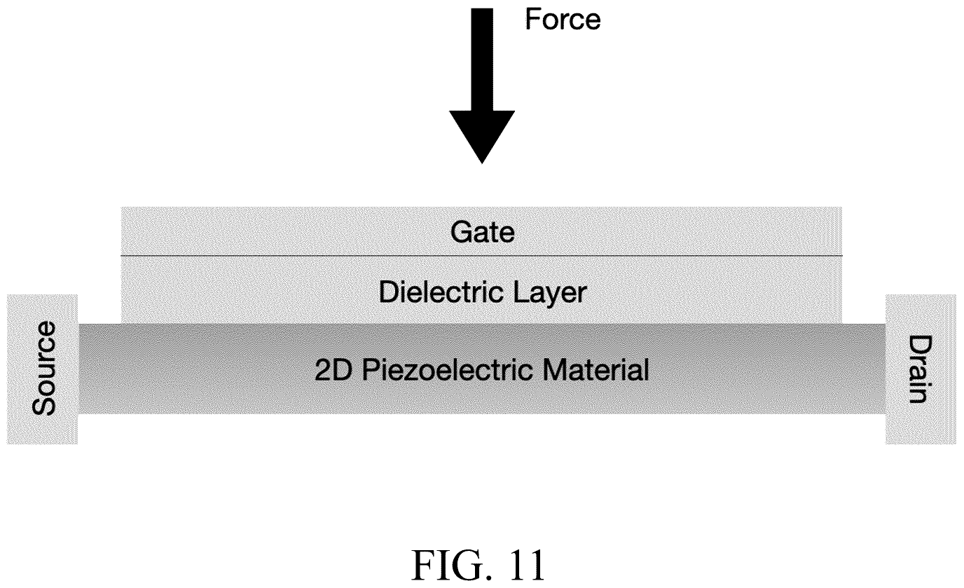

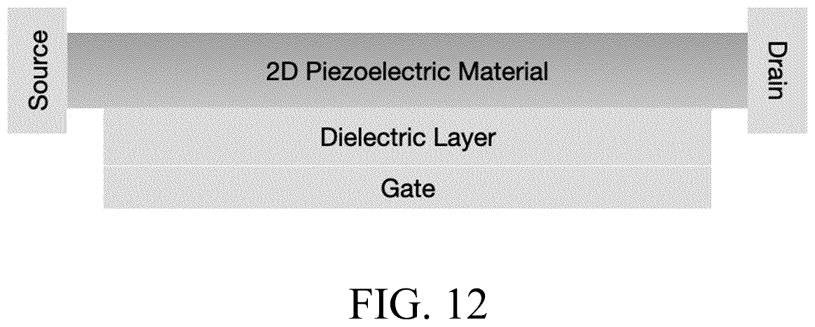

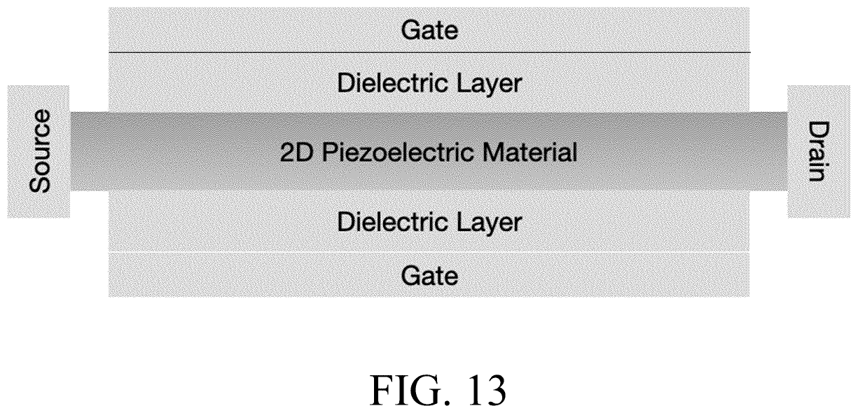

Shown in FIG. 11 is a piezoelectric thin-film transistor. When subjected to positive stress (as shown), a positive piezoelectric charge is induced at the interface between the semiconductor and insulator (facing the gate side). Similarly, a negative stress yields opposite piezoelectric charge results. The piezoelectric charge developed at the gate side can influence the surface potential of the transistor, leading to modulations in the width of the depletion region and the flat-band voltage. Simultaneously, the piezoelectric charge on the film's reverse side can either accumulate or deplete charges. FIGS. 12-13 illustrate variations of the piezoelectric thin-film transistor structure having different layer, gate, source, and drain positions, though the primary functionality of the system is unchanged.

Various aspects described herein may be embodied as systems or methods. Accordingly, various aspects herein may take the form of an entirely hardware aspect, an entirely software aspect (including firmware, resident software, micro-code, etc.), or an aspect combining software and hardware aspects These aspects can all generally be referred to herein as a “service,” “circuit,” “circuitry,” “module,” or “system.”

Furthermore, various aspects herein may be embodied as computer program products including computer readable program code stored on a tangible non-transitory computer readable medium. Such a medium can be manufactured as is conventional for such articles, e.g., by pressing a CD-ROM. The program code includes computer program instructions that can be loaded into processor (202) (and possibly also other processors), to cause functions, acts, or operational steps of various aspects herein to be performed by the processor (202) (or another processor). Computer program code for carrying out operations for various aspects described herein may be written in any combination of one or more programming language(s) and can be loaded from disk (220) into code memory (218) for execution. The program code may execute, e.g., entirely on processor (202), partly on processor (202) and partly on a remote computer connected to network (210), or entirely on the remote computer.

While examples, one or more representative embodiments and specific forms of the disclosure have been illustrated and described in detail in the drawings and foregoing description, the same is to be considered as illustrative and not restrictive or limiting. The description of particular features in one embodiment does not imply that those particular features are necessarily limited to that one embodiment. Some or all of the features of one embodiment can be used in combination with some or all of the features of other embodiments as would be understood by one of ordinary skill in the art, whether or not explicitly described as such. One or more exemplary embodiments have been shown and described, and all changes and modifications that come within the spirit of the disclosure are desired to be protected.

I/we claim:

1. A piezoelectric material system, comprising:
(a) a heterostructure, including:
(i) a first material, and
(ii) a second material positioned over the first material, wherein the first and second materials form a heterojunction defining a collective material property of the heterostructure; and
(b) a material adjustment mechanism configured to maintain the heterojunction at a user-specified interaction between the first and second materials, wherein the material adjustment mechanism is selectively operable to adjust the user-specified interaction to thereby adjust the collective material property;
wherein the user-specified interaction includes at least one of a distance, twist angle, defect density, defect charge, polarization, corrugation, or coupling strength between the first and second materials.

2. The piezoelectric material system of claim 1, wherein the collective material property includes at least one of piezoelectricity, polarization, charge conductance, heat conductance, ON current, OFF current, or subthreshold slope.

3. The piezoelectric material system of claim 1, wherein the material adjustment mechanism is configured to apply an external strain onto the heterostructure.

4. The piezoelectric material system of claim 1, wherein the material adjustment mechanism is configured to apply an internal strain onto the heterostructure.

5. The piezoelectric material system of claim 1, wherein the material adjustment mechanism is configured to adjust a temperature of the heterostructure.

6. The piezoelectric material system of claim 1, wherein the material adjustment mechanism is configured to apply an external electric field across the heterostructure.

7. The piezoelectric material system of claim 1, wherein the material adjustment mechanism is configured to apply an internal electric current through the heterostructure.

8. The piezoelectric material system of claim 1, wherein the material adjustment mechanism includes one or more additional materials configured to apply a vicinity effect to the heterostructure.

9. The piezoelectric material system of claim 1, wherein the material adjustment mechanism is configured to adjust a twist angle between the first material and the second material of the heterostructure.

10. The piezoelectric material system of claim 1, wherein the material adjustment mechanism is configured to apply a heat current to the heterostructure.

11. The piezoelectric material system of claim 1, wherein the material adjustment mechanism is configured to apply a material defect to at least one of the first material or the second material.

12. The piezoelectric material system of claim 1, wherein the material adjustment mechanism is configured to apply a corrugation to at least one of the first material or the second material.

13. The piezoelectric material system of claim 1, comprising a material enclosure configured to encapsulate the heterostructure.

14. The piezoelectric material system of claim 1, wherein the user-specified interaction includes one of a Coulomb interaction, a quantum mechanical interaction, a phonon interaction, a short-range interaction, or a long-range interaction.

15. The piezoelectric material system of claim 1, wherein the first material includes a 3D material, a 2D material, a transition metal dichalcogenide, an oxide, a metal, a group IV element, a group III-V element, a group II-VI element, or an alloy.

16. The piezoelectric material system of claim 1, wherein the second material includes a 3D material, a 2D material, a transition metal dichalcogenide, an oxide, a metal, a group IV element, a group III-V element, a group II-VI element, or an alloy.

17. A piezoelectric material system, comprising:
(a) a heterostructure, including:
(i) a first material, and
(ii) a second material positioned over the first material, wherein the first and second materials form a heterojunction defining a collective material property of the heterostructure; and
(b) a material adjustment mechanism configured to maintain the heterojunction at a user-specified material interaction, wherein the material adjustment mechanism is selectively operable to adjust the user-specified material interaction to thereby adjust the collective material property;
wherein the collective material property includes at least one of piezoelectricity, polarization, charge conductance, heat conductance, ON current, OFF current, or subthreshold slope.

18. The piezoelectric material system of claim 17, wherein the material adjustment mechanism is configured to apply to the heterostructure at least one of an external strain, an internal strain, a temperature change, an external electric field, an internal electric current, a vicinity effect, a twist angle change, a charge current, a heat current, a defect, or a corrugation.

19. A piezoelectric material system, comprising:
(a) a heterostructure, including:
(i) a first material, and
(ii) a second material positioned over the first material, wherein the first and second materials form a heterojunction defining a collective material property of the heterostructure; and
(b) a material adjustment mechanism configured to maintain the heterojunction at a user-specified material interaction, wherein the material adjustment mechanism is selectively operable to adjust the user-specified material interaction to thereby adjust the collective material property;
wherein the first material includes a 3D material, a 2D material, a transition metal dichalcogenide, an oxide, a metal, a group IV element, a group III-V element, a group II-VI element, or an alloy, and wherein the second material includes a 3D material, a 2D material, a transition metal dichalcogenide, an oxide, a metal, a group IV element, a group III-V element, a group II-VI element, or an alloy.

20. The piezoelectric material system of claim 19, wherein the material adjustment mechanism is configured to apply to the heterostructure at least one of an external strain, an internal strain, a temperature change, an external electric field, an internal electric current, a vicinity effect, a twist angle change, a charge current, a heat current, a defect, or a corrugation.
